(19) United States
(12) Patent Application Publication
(10) Pub. No.: US 2021/0269673 A1
(43) Pub. Date: Sep. 2, 2021

(54) POLISHING COMPOSITION CONTAINING ZIRCONIA PARTICLES AND AN OXIDIZER

(71) Applicant: FUJIMI CORPORATION, Tualatin, OR (US)

(72) Inventor: Jie Lin, Tualatin, OR (US)

(73) Assignee: FUJIMI CORPORATION, Tualatin, OR (US)

(21) Appl. No.: 16/805,037

(22) Filed: Feb. 28, 2020

(51) Int. Cl. C09G 1/02; H01L 21/3105

(52) U.S. Cl. CPC C09G 1/02; H01L 21/31053

(57) ABSTRACT

Provided herein are compositions and methods for polishing surfaces comprising amorphous carbon, spin-on carbon (SoC), and/or diamond like carbon (DLC) films.

### TECHNICAL FIELD

The present technology generally relates to compositions and methods for polishing surfaces comprising amorphous carbon, spin-on carbon (SoC), and/or diamond like carbon (DLC) films.

### BACKGROUND

One of the major chemical mechanical polishing (CMP) challenges for semiconductor manufacturing is the selective polishing certain materials. Carbon and DLC films have been increasingly used in integrated circuit (IC) fabrication. U.S. Pat. No. 6,673,684; D. S. Hwang, et al., Diamond and Related Materials, 13 (11-12): 2207-2210 (2004); Franz Kreupl, et al. Electron Devices Meeting, 2008. Traditional methods are ineffective in polishing DLC films (H. Y. Tsai, et al., Diamond and Related Materials. 16 (2)) and chemical enhancements including oxidation have been employed to improve removal rate (Zewei Yuan, et al., J. Manuf. Sci. Eng. 135(4): 041006 (2013); Evan L. Hl et al., Carbon 68: 473-479 (2014); Jessica M. Werrell, et al., J. Sci. Techn. Adv. Materials 18 (1): 654-663; Soumen Mandal, et al., Carbon, 130: 25-30 (2018)). However, the removal rate is still too low for leading edge CMP.

Accordingly, a need exists for novel CMP compositions that can effectively and efficiently polish amorphous carbon, SoC, and/or DLC films.

### SUMMARY OF THE DISCLOSURE

Provided herein are compositions and methods for polishing surfaces comprising amorphous carbon, SoC, and/or DLC films.

Embodiments include a method of increasing the removal rate of amorphous carbon, SoC, or DLC from a surface, comprising contacting the surface with a slurry comprising an abrasive having zirconia particles and a metal-containing oxidizer, and polishing the surface. In some embodiments, the removal rate is increased when compared to a removal rate using a similar slurry composition having silica and/or a non-metal-containing oxidizer in place of zirconia particles and/or the metal-containing oxidizer. In some embodiments, the zirconia particle is an aggregate comprising primary particles. In some embodiments, the zirconia particle comprises a primary particle size with a diameter of about 8-10 nm and a secondary size of the aggregates with a diameter of about 70 nm. In some embodiments, the metal-containing oxidizer comprises an element selected from the group consisting of manganese, cerium, vanadium, and iron. In some embodiments, the metal-containing oxidizer is selected from the group consisting of KMnO₄, (NH₄)₂Ce(NO₃)₆, NaVO₃, NH₄VO₃, and Fe(NO₃)₃. In some embodiments, the composition has a pH of about 3 to about 6. In some embodiments, the zirconia particles are present in an amount of about 0.2 wt. % of more. In some embodiments, the zirconia particles are present in an amount of about 2.5 wt. % of less. In some embodiments, the metal-containing oxidizer present in an amount of about 2 mM or more. In some embodiments, the zirconia particles comprise colloidal zirconia. In some embodiments, the zirconia particles comprise calcined zirconia.

Other embodiments include a chemical mechanical polishing (CMP) composition comprising colloidal zirconia particles and a metal-containing oxidizer. In some embodiments, the colloidal zirconia particle is an aggregate comprising primary particles. In some embodiments, the colloidal zirconia particle comprises a primary particle size with a diameter of about 8 to about 10 nm and a secondary size of the aggregates with a diameter of about 70 nm. In some embodiments, the metal-containing oxidizer comprises an element selected from the group consisting of manganese, cerium, vanadium, and iron. In some embodiments, the metal-containing oxidizer is selected from the group consisting of KMnO₄, (NH₄)₂Ce(NO₃)₆, NaVO₃, NH₄VO₃, and Fe(NO₃)₃. In some embodiments, the composition has a pH of about 3 to about 6. In some embodiments, the zirconia particles are present in an amount of about 0.2 wt. % of more. In some embodiments, the zirconia particles are present in an amount of about 2.5 wt. % of less. In some embodiments, the metal-containing oxidizer is present in an amount of about 2 mM or more. Embodiments also include a reaction product formed by contacting the CMP composition of the embodiments with an amorphous carbon, SoC, or DLC surface.

### DETAILED DESCRIPTION

Provided herein are CMP compositions and methods for polishing surfaces comprising amorphous carbon, SoC, and/or DLC films. As used herein, the term “chemical mechanical polishing” or “planarization” refers to a process of planarizing (polishing) a surface with the combination of surface chemical reaction and mechanical abrasion. In some embodiments, the chemical reaction is initiated by applying to the surface a composition (interchangeably referred to as a ‘polishing slurry,’ a ‘polishing composition,’ a ‘slurry composition’ or simply a ‘slurry’) capable of reacting with a surface material, thereby turning the surface material into a product that can be more easily removed by simultaneous mechanical abrasion. In some embodiments, the mechanical abrasion is performed by contacting a polishing pad with the surface, and moving the polishing pad relative to the surface. DLC is used herein in accordance with how the term is understood in the art, and includes a variety of amorphous hydrogenated or nonhydrogenated forms of carbon which are metastable materials characterized by a mixture of sp2 and sp3 hybridized carbon bonds. DLC used in ICs is included within the meaning of the term.

Composition

The CMP polishing compositions disclosed herein can comprise, consist essentially of, or consist of one or more of the following components.

Abrasive

The CMP compositions of the present disclosure contain at least one abrasive having zirconia particles. In some embodiments, the zirconia particles are colloidal zirconia particles or milled/calcined zirconia particles. The abrasive in the CMP composition provides or enhances mechanical abrasion effects during the CMP process.

In some embodiments, the zirconia (e.g., colloidal zirconia or milled/calcined zirconia) particle is an aggregate comprising primary particles, and optionally secondary particles. It will be understood that aggregates may be formed from a combination of individual particles, and these individual particles are known in the art as primary particles, whereas the agglomerated combination of particles are known in the art as secondary particles. The abrasive in the polishing composition can be in a form of primary particles or in a form of secondary particles which are aggregates of primary particles. Alternatively, the abrasive may be present both in the primary particle form and secondary particle form. In a preferable embodiment, the abrasive is present at least partially in a secondary particle form in the polishing composition.

In some embodiments, the zirconia (e.g., colloidal zirconia or milled/calcined zirconia) particle comprises an average primary particle diameter (Dpi) with a diameter of less than 15 nm, e.g., about 8-10 nm. In some embodiments, the zirconia (e.g., milled/calcined zirconia) particle comprises an average primary particle diameter (Dpi) with a diameter of about 20-110 nm, e.g., about 20, about 25, about 30, about 40, about 50, about 60, about 70, about 80, about 90, about 100, or about 110 nm, or a range therein between. The abrasive's average primary particle diameter (Dpi) can be determined, for instance, from the specific surface area S (m²/g) measured by the BET method, based on the equation for the average primary particle diameter Dpi (nm)=2727/S. The abrasive's specific surface area can be measured by using, for instance, a surface area analyzer under trade name “FLOW SORB II 2300” available from Micromeritics.

The average secondary particle diameter (D_{P2}) of the abrasive is not particularly limited. From the standpoint of the polishing rate, etc., it is preferably 20, 30, 40, 50, 60, 65, 70, 75, or 80 nm or larger. From the standpoint of obtaining greater effects of polishing, the average secondary particle diameter D_{P2} is preferably 60 nm or larger, more preferably 65 nm or larger, or yet more preferably 70 nm or larger. In some embodiments, the secondary particle diameter of the aggregates is a diameter of about 60, 65, 70, 75, or 80 nm, or a range therein between. In some embodiments, the zirconia (e.g., milled/calcined zirconia) particle comprises an average secondary particle diameter (D_{P2}) with a diameter of about 80 to 2000 nm. In some embodiments, the secondary particle diameter of the aggregates is a diameter of about 80, 90, 100, 150, 200, 300, 400, 500, 600, 700, 800, 900, 1000, 1100, 1200, 1300, 1400, 1500, 1600, 1700, 1800, 1900, 2000 nm, or a range therein between.

The abrasive's average secondary particle diameter D_{P2} can be measured for an aqueous dispersion of the abrasive of interest (dispersion having a water-soluble polymer-free composition) as a measurement sample by dynamic light scattering using, for instance, model “UPA-UT151” available from Nikkiso Co., Ltd.

In some embodiments, the present CMP composition comprises about 0.1% to about 3% by weight of the zirconia (e.g., colloidal zirconia or milled/calcined zirconia) particle abrasive. For example, the present CMP composition may comprise about 0.1, 0.2, 0.3, 0.4, 0.5, 0.6, 0.7, 0.8, 0.9, 1.0, 1.1, 1.2, 1.3, 1.4, 1.5, 1.5, 1.6, 1.7, 1.8, 1.9, 2.0, 2.1, 2.2, 2.3, 2.4, 2.5, 2.6, 2.7, 2.8, 2.9, or 3.0% by weight of the zirconia (e.g., colloidal zirconia or milled/calcined zirconia) particle abrasive.

Metal-Containing Oxidizer

The CMP compositions of the present disclosure may also contain at least one metal-containing oxidizer. An oxidizer may be added to the present CMP composition to oxidize a surface of a polishing object, thereby enhancing the removal rate of the CMP process. In some embodiments, an oxidizer is added to the CMP composition only prior to use. In other embodiments, an oxidizer is mixed with other ingredients of the CMP composition at approximately the same time during a manufacturing procedure. In some embodiments, the present composition is manufactured and sold as a stock composition, and an end customer can choose to dilute the stock composition as needed and/or add a suitable amount of an oxidizer before using.

Examples of the metal in the metal-containing oxidizer which may be used include, but are not limited to, manganese, cerium, vanadium, and iron. Examples of the metal-containing oxidizer which may be used include, but are not limited to, KMnO₄, (NH₄)₂Ce(NO₃)₆, NaVO₃, NH₄VO₃, and Fe(NO₃)₃.

Suitable content of the metal-containing oxidizer can be determined based on particular needs. In some embodiments, content of the metal-containing oxidizer in the CMP composition is about 2 mM or more. For example, the content of the metal-containing oxidizer may be about 2, 3, 4, 5, 6, 7, 8, 9, 10, 15, 20, 25, 30, 35, 40, 45, 50, 55, 60, 65, 70, or 75 mM, or a range therein between.

pH Adjusting Agent

In some embodiments, the present CMP composition further comprises at least one pH adjusting agent. In some embodiments, the pH of the present CMP composition is, although not particularly limited, in the range of about 3 to about 6, inclusive of the end points. For example, in some embodiments, the pH of the present CMP composition is about 3, 3.2, 3.4, 3.6, 3.8, 4, 4.2, 4.4, 4.6, 4.8, 5, 5.2, 5.4, 5.6, 5.8, 6, or 6.2, or a range therein between.

In some embodiments, an acid is used as the pH adjusting agent. The acid used in connection with the present invention can be organic or inorganic compounds. Examples of the acid include inorganic acids such as sulfuric acid, nitric acid, boric acid, carbonic acid, hypophosphorous acid, phosphorous acid, and phosphoric acid; and organic acids such as carboxylic acids including formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, and lactic acid, and organic sulfuric acids including methanesulfonic acid, ethanesulfonic acid, and isethionic acid.

Content of the acid in the CMP composition is not particularly limited as long as it is an amount allowing the CMP composition to be within the aforementioned pH range.

Other Components

The CMP composition of the present invention may contain, if necessary, other components, such as a preservative, a biocide, a reducing agent, a polymer, a surfactant, or the like.

In some embodiments, the CMP composition according to the present disclosure may also comprise a biocide or other preservatives. Examples of preservatives and biocides that may be used in connection with the present invention include an isothiazoline-based preservative such as 2-methyl-4-isothiazolin-3-one or 5-chloro-2-methyl-4-isothiazolin-3-one, paraoxybenzoate esters, and phenoxyethanol, and the like. These preservatives and biocides may be used either alone or in mixture of two or more kinds thereof.

In some embodiments, the CMP composition does not contain a non-metal-containing oxidizer, such as H₂O₂, hydroxylamine, NH₄IO₄, and (NH₄)₂S₂O₈.

In some embodiments, the CMP composition does not contain an abrasive other than zirconia particles, such as silica, alumina, ceria, and titania particles. In some embodiments, the CMP composition does not contain an abrasive other than colloidal zirconia particles. For example, the composition may not contain an abrasive like spherical zirconia particles.

Methods and Compositions

In another aspect of the present disclosure, provided herein are methods for CMP of an object having at least one surface. The method comprises contacting the surface with a polishing pad; delivering a CMP composition according to the present disclosure to the surface; and polishing said surface with the CMP composition. In some embodiments, the surface includes amorphous carbon, SoC, and/or DLC.

Examples of the polished object to be polished may contain silicon nitride, silicon oxide, amorphous silicon (a-Si) or polysilicon.

In this regard, examples of the polished object to be polished containing silicon oxide include a tetraethyl orthosilicate (TEOS)-type silicon oxide film formed by using tetraethyl orthosilicate as a precursor (hereinafter, also simply referred to as “TEOS”), a high discharge pressure (HDP) film, an undoped silicate glass (USG) film, a phosphorous silicate glass (PSG) film, a borophosphosilicate glass (BPSG) film, and a rapid thermal oxide (RTO) film.

In another aspect of the present disclosure, provided herein are methods for increasing the removal rate of amorphous carbon, SoC, or DLC from a surface, comprising contacting the surface with a slurry comprising an abrasive having zirconia particles and a metal-containing oxidizer, and polishing the surface. In some embodiments, the removal rate is increased when compared to a removal rate using a similar slurry composition having silica and/or a non-metal-containing oxidizer in place of zirconia particles and/or the metal-containing oxidizer. In some embodiments, the slurry is a CMP composition according to the present disclosure.

In another aspect of the present disclosure, provided herein are systems for chemical mechanical polishing (CMP). The system comprises a substrate comprising at least one surface having amorphous carbon, SoC, or DLC material, a polishing pad, and a CMP composition according to the present disclosure.

In yet another aspect of the present disclosure, provided herein is a substrate comprising at least one surface having amorphous carbon, SoC, or DLC, wherein the substrate is in contact with a chemical mechanical polishing (CMP) composition according to the present disclosure.

In some embodiments, the present methods and compositions are suitable for polishing an amorphous carbon, SoC, or DLC surface. An apparatus or conditions commonly used for Co polishing can be adopted and modified according to particular needs. The selections of a suitable apparatus and/or conditions for carrying out the present methods are within the knowledge of a skilled artisan.

In some embodiments, the present methods result in amorphous carbon, SoC, or DLC removal rate of greater than about 40, 60, 80, 85, 90, 100, 120, 140, 160, 180, 200, 300, 400, 500, 600, 700, 800, 900, or 1,000 Å/min.

It is noted that, as used herein and in the appended claims, the singular forms “a”, “an”, and “the” include plural referents unless the context clearly dictates otherwise. It is further noted that the claims may be drafted to exclude any optional element. As such, this statement is intended to serve as antecedent basis for use of such exclusive terminology as “solely”, “only” and the like in connection with the recitation of claim elements, or use of a “negative” limitation.

The term “about” will be understood by persons of ordinary skill in the art and will vary to some extent depending upon the context in which it is used. If there are uses of the term which are not clear to persons of ordinary skill in the art given the context in which it is used, “about” will mean up to plus or minus 10% of the particular term. Certain ranges are presented herein with numerical values being preceded by the term “about”. The term “about” is used herein to provide literal support for the exact number that it precedes, as well as a number that is near to or approximately the number that the term precedes. In determining whether a number is near to or approximately a specifically recited number, the near or approximating unrecited number may be a number, which, in the context in which it is presented, provides the substantial equivalent of the specifically recited number.

Where a range of values is provided, it is understood that each intervening value, to the tenth of the unit of the lower limit unless the context clearly dictates otherwise, between the upper and lower limit of that range and any other stated or intervening value in that stated range, is encompassed within the invention. The upper and lower limits of these smaller ranges may independently be included in the smaller ranges and are also encompassed within the invention, subject to any specifically excluded limit in the stated range. Where the stated range includes one or both of the limits, ranges excluding either or both of those included limits are also included in the invention.

This disclosure is not limited to particular embodiments described, as such may, of course, vary. It is also to be understood that the terminology used herein is for the purpose of describing particular embodiments only, and is not intended to be limiting, since the scope of the present invention will be limited only by the appended claims.

As will be apparent to those of skill in the art upon reading this disclosure, each of the individual embodiments described and illustrated herein has discrete components and features which may be readily separated from or combined with the features of any of the other several embodiments without departing from the scope or spirit of the present invention. Any recited method can be carried out in the order of events recited or in any other order that is logically possible.

All publications and patents cited in this specification are herein incorporated by reference as if each individual publication or patent were specifically and individually indicated to be incorporated by reference and are incorporated herein by reference to disclose and describe the methods and/or materials in connection with which the publications are cited. The citation of any publication is for its disclosure prior to the filing date and should not be construed as an admission that the present invention is not entitled to antedate such publication by virtue of prior invention. Further, the dates of publication provided may be different from the actual publication dates that may need to be independently confirmed.

The following examples are given for the purpose of illustrating various embodiments of the disclosure and are not meant to limit the present disclosure in any fashion. One skilled in the art will appreciate readily that the present disclosure is well adapted to carry out the objects and obtain the ends and advantages mentioned, as well as those objects, ends and advantages inherent herein. The present examples, along with the methods described herein are presently representative of embodiments and are exemplary, and are not intended as limitations on the scope of the disclosure. Changes therein and other uses which are encompassed within the spirit of the disclosure as defined by the scope of the claims will occur to those skilled in the art.

### EXAMPLES

### Example 1: Effect of Particle and Oxidizer on Removal Rate

Slurries with silica or zirconia particles and certain oxidizers were prepared, and a benchtop polisher was used to polish a diamond-like carbon (DLC) film surface. The results are shown in Table 1.

TABLE 1

| | | Removal rate |
|---|---|---|
| Particle | Oxidizer | (Å/min) |
| Silica | none | 3 |
| (1%) | permanganate | 17 |
| Zirconia | none | 4 |
| (1%) | periodate | 5 |
| | persulfate | 14 |
| | permanganate | 121 |

*Oxidizer at same concentration of 25 mM, pH = 5.2
*Benchtop polisher: Multiprep, Allied High Tech Products, Inc. Fuji bo H7000 pad, 2p5i, platen/head = 200/23 rpm, 50 mL/min

Slurries with silica or zirconia particle only produce very low removal rate. So, an oxidizer is added to oxidize the surface of carbon film in order to mechanically polish the film. Slurries based on zirconia particle with periodate and persulfate do not produce high removal rate (only 5 and 14 Å/min, respectively). A slurry with zirconia particle and permanganate oxidizer produces much higher removal rate (121 Å/min) than slurries with periodate and persulfate (5 and 14 Å/min).

Synergetic effect of zirconia and permanganate: As shown above, slurries based on zirconia particles with strong nonmetal-containing oxidizers persulfate and periodate do not produce high removal rate. A slurry with silica and permanganate does not produce high removal rate. The combination of metal oxide zirconia particle and metal-containing permanganate produces much higher removal rate. Therefore, there is a synergetic effect by the combination of zirconia particle and permanganate oxidizer. While not bound by theory, permanganate is believed to help oxidize surface of carbon film and form C—O—Mn bond while zirconia particles are attracted to the surface to enhance mechanical polishing. Zirconia particle and permanganate oxidizer work together to produce very high removal rate.

### Example 2: Effect of pH

CMP compositions comprising the same concentration of zirconia and permanganate were produced at different pH. A benchtop polisher using the various CMP compositions was used to polish a DLC surface. The results are shown in Table 2.

TABLE 2

| | EC | Removal rate |
|---|---|---|
| pH | (mS/cm) | (Å/min) |
| 2.3 | 4.79 | 79 |
| 3.6 | 2.60 | 147 |
| 5.2 | 4.34 | 121 |
| 6.7 | 5.10 | 50 |

*Zirconia particle = 1%, permanganate = 25 mM

Table 2 shows that removal rate is high in pH 3.6-5.2 but becomes lower at pH of 2.3 and a basic pH. While not bound by theory, the removal rate vs. pH observed is believed to be a combined effect of multiple processes including pH effect on oxidation of DLC film by permanganate, pH effect on zeta potential of zirconia particle and DLC film, and pH effect on charge-charge interaction between particle and film.

### Example 3: Effect of Zirconia Concentration on Removal Rate

CMP compositions comprising the same concentration of permanganate and pH were produced at different concentration of zirconia. The results are shown in Table 3.

TABLE 3

| Zirconia particle | Removal rate |
|---|---|
| (wt %) | (Å/min) |
| 0.1% | 59 |
| 0.3% | 132 |
| 0.5% | 149 |
| 1.0% | 151 |
| 3.0% | 96 |

*pH = 3.6, permanganate = 25 mM

Table 3 shows that wt % of zirconia particle in the range of above 0.1% to less than 3% does not have a significant effect on removal rate. This indicates that 0.3% of zirconia particle is sufficient to produce high removal rate. Removal rate drops off significantly when wt % of zirconia decreases from 0.3% to 0.1%. Removal rate also decreases when wt % of zirconia increases from 1.0% to 3.0%.

### Example 4: Effect of KMnO₄ Concentration on Removal Rate

CMP compositions comprising the same concentration of zirconia and pH were produced at different concentration of permanganate. The results are shown in Table 4.

TABLE 4

| Permanganate | EC | Removal rate |
|---|---|---|
| (mM) | (mS/cm) | (Å/min) |
| 1.3 | 0.28 | 87 |
| 3.2 | 0.50 | 122 |
| 6.3 | 0.85 | 137 |
| 25 | 3.00 | 161 |
| 63 | 5.90 | 162 |

*Zirconia particle = 1%, pH = 3.6

Table 4 shows that removal rate increases when permanganate increases from 3.2 to 25 mM. At the lower end, removal rate drops off significantly when permanganate decreases to 1.3 mM.

### Example 5: Effect of Zirconia Particle

CMP compositions comprising the same concentration of zirconia, permanganate and pH were produced at different types of zirconia. The results are shown in Table 5.

TABLE 5

| | Mean particle size (nm) | | Removal rate |
|---|---|---|---|
| Zirconia particle | primary | secondary | (Å/mm) |
| current-colloidal | ~8-10 | ~70 | 145 |
| other-milled/calcined | ~25-100 | ~150 | 45 |
| other-milled/calcined | ~100 | ~1400 | 130 |

*pH = 3.6, zorconia particle = 0.5%, permanganate = 25 mM
*Secondary particle size measured on Malvern Zetasizer Nano ZS

Table 5 shows that removal rate is efficient with calcined zirconia in addition to colloidal zirconia.

### Example 6: SoC Polishing

TABLE 6

| Oxidizer and | | Removal rate (Å/min) | | |
|---|---|---|---|---|
| concentration | | SoC | TEOS | a-Si |
| None | — | 36 | <5 | <5 |
| H₂O₂ | 260 mM | 37 | <5 | <5 |
| (NH₄)₂S₂O₈ | 9 mM | 43 | <5 | <5 |
| KMnO₄ | 0.2 mM | 1180 | <5 | <5 |

*Colloidal zirconia particle = 0.03%, pH = 4.1

Table 6 shows that slurry based on 0.03% colloidal zirconia does not produce high SoC removal rate using peroxide and persulfate, i.e. H₂O₂ and (NH₄)₂S₂O₈, as oxidizer. When KMnO₄ is used as oxidizer, however, zirconia slurry produces very high SoC removal rate but very low TEOS and SoC removal rates. Therefore, the slurry achieves very high SoC/TEOS and SoC/a-Si selectivities using very low concentrations of zirconia and KMnO4.

What is claimed is:

1. A method of increasing the removal rate of amorphous carbon, spin-on carbon (SoC), or diamond like carbon (DLC) from a surface, comprising contacting the surface with a slurry comprising an abrasive having zirconia particles and a metal-containing oxidizer, and polishing the surface.

2. The method of claim 1, wherein the removal rate is increased when compared to a removal rate using a similar slurry composition having silica and/or a non-metal-containing oxidizer in place of zirconia particles and/or the metal-containing oxidizer.

3. The method of claim 1, wherein the zirconia particle is an aggregate comprising primary particles.

4. The method of claim 3, wherein the zirconia particle comprises a primary particle size with a diameter of about 8-10 nm and a secondary size of the aggregates with a diameter of about 70 nm.

5. The method of claim 1, the metal-containing oxidizer comprises an element selected from the group consisting of manganese, cerium, vanadium, and iron.

6. The method of claim 1, wherein the metal-containing oxidizer is selected from the group consisting of KMnO₄, (NH₄)₂Ce(NO₃)₆, NaVO₃, NH₄VO₃, and Fe(NO₃)₃.

7. The method of claim 1, wherein the composition has a pH of about 3 to about 6.

8. The method of claim 1, wherein the zirconia particles are present in an amount of about 0.2 wt. % of more.

9. The method of claim 1, wherein the zirconia particles are present in an amount of about 2.5 wt. % of less.

10. The method of claim 1, wherein the metal-containing oxidizer. present in an amount of about 2 mM or more.

11. The method of claim 1, wherein the zirconia particles comprise colloidal zirconia.

12. The method of claim 1, wherein the zirconia particles comprise calcined zirconia.

13. A chemical mechanical polishing (CMP) composition comprising colloidal zirconia particles and a metal-containing oxidizer.

14. The CMP composition of claim 13, wherein the colloidal zirconia particle is an aggregate comprising primary particles.

15. The CMP composition of claim 14, wherein the colloidal zirconia particle comprises a primary particle size with a diameter of about 8 to about 10 nm and a secondary size of the aggregates with a diameter of about 70 nm.

16. The CMP composition of claim 13, wherein the metal-containing oxidizer comprises an element selected from the group consisting of manganese, cerium, vanadium, and iron.

17. The CMP composition of claim 13, wherein the metal-containing oxidizer is selected from the group consisting of KMnO₄, (NH₄)₂Ce(NO₃)₆, NaVO₃, NH₄VO₃, and Fe(NO₃)₃.

18. The CMP composition of claim 13, wherein the composition has a pH of about 3 to about 6.

19. The CMP composition of claim 13, wherein the zirconia particles are present in an amount of about 0.2 wt. % of more.

20. The CMP composition of claim 19, wherein the zirconia particles are present in an amount of about 2.5 wt. % of less.

21. The CMP composition of claim 19, wherein the metal-containing oxidizer. present in an amount of about 2 mM or more.

22. A reaction product formed by contacting the CMP composition of claim 13 with an amorphous carbon, spin-on carbon (SoC), or DLC surface.
